(19) United States
(12) Patent Application Publication
(10) Pub. No.: US 2010/0175286 A1
(43) Pub. Date: Jul. 15, 2010

(54) NAME BADGE WITH ILLUMINATED GRAPHIC DISPLAY

(76) Inventor: Perry Dean Felix, Houston, TX (US)

Correspondence Address: WILLIAMS, MORGAN & AMERSON, 10333 RICHMOND, SUITE 1100, HOUSTON, TX, 77042, US

(21) Appl. No.: 12/687,051

(22) Filed: Jan. 13, 2010

Related U.S. Application Data
(60) Provisional application No. 61/204,926, filed on Jan. 13, 2009.

(51) Int. Cl. A44C 3/00; G09F 13/00; H05B 37/02; B23P 11/00; H05K 13/00

(52) U.S. Cl. 40/1.5; 315/313; 29/428; 29/592.1

(57) ABSTRACT

A name badge comprises a frame with a cavity from front to rear. A rear plate, juxtaposed with the frame rear surface, includes a printed circuit. A front plate, with a window, is juxtaposed with the frame front surface.

A transparent graphic display plate, having graphic elements, is disposed within the frame cavity. The graphic elements are 3-D laser etched in reverse through the rear surface of the graphic display plate and viewed in proper orientation from the front. The graphic elements are illuminated from two or more edges. Illumination modules are arrayed in cutouts at the bottom edge and right and left ends of the frame. Each illumination module contains a plurality of LEDs, and a digital logic circuit.

Button batteries are held in cutouts on the frame. A switch is mounted in a cutout on the frame. The digital logic circuit selectively activates the LEDs in a predetermined sequence, such as: flashing, strobe, sweep, fade, single color, multiple colors, random order, and sequential order.

### CROSS-REFERENCE TO RELATED APPLICATIONS

Reference is hereby made to provisional patent application titled, “Glowbadge;” filed by Perry Dean Felix, of Houston, Tex., on Jan. 13, 2009, Ser. No. 61/204,926. The prior application is expressly incorporated herein by reference.

### STATEMENT REGARDING FEDERALLY SPONSORED RESEARCH OR DEVELOPMENT

Not Applicable

### BACKGROUND OF THE INVENTION

This invention relates to the field of name badges, and more particularly to a name badge with a graphic display illuminated by light-emitting diodes.

Name badges, heretofore, have been printed on paper, inserted into plastic sleeves, and pinned onto clothing. While inexpensive, these badges do not catch and hold one's attention. They are not noticed across a crowded room. They do not speak to the innovative and technologically savvy character of the badge holder. A name badge that is illuminated will catch the eyes of prospective clients at a trade show. A name badge having custom three-dimensional graphics and indicia will demonstrate the technological sophistication of the badge holder. Such a name badge is part of an aggressive overall marketing strategy that is necessary in a competitive commercial climate.

Laser etching machines are available that will carve finely detailed three-dimensional graphic artwork, logos, letters and numbers into transparent plastic material. These computer-controlled machines are ideal for fabricating the graphic display from an artist's rendering. The laser can etch the graphic artwork in reverse on the rear aspect of the plastic material, leaving the front smooth and unbroken.

Light Emitting Diodes, or LED's are available that draw very little power. These will be combined with circuitry, well known to those skilled in the art, that will power the LED's on and off in a predetermined sequence, and in a variety of colors.

Accordingly, there is a need to provide a name badge that has an illuminated graphic display, to draw attention to the badge holder.

There is a further need to provide a name badge with an illuminated graphic display of the type described and that is laser etched for fine detail and a smooth face.

There is a yet further need to provide a name badge with an illuminated graphic display of the type described and that is illuminated by LED's for brilliant luminosity in a small space, with low power consumption and long battery life.

There is a still further need to provide a name badge with an illuminated graphic display of the type described and wherein the LED's are turned on and off by control circuitry in a predetermined sequence and selective colors.

There is another need to provide a name badge with an illuminated graphic display of the type described and that can be manufactured cost-effectively in large quantities of high quality.

### BRIEF SUMMARY OF THE INVENTION

In accordance with the present invention, there is provided a name badge 30 to be worn on clothing. The name badge 30 comprises a frame 32 extending between opposite top 34 and bottom 36 edges, right 38 and left 40 ends, and front 42 and rear 44 surfaces. The frame 32 has a cavity 46 extending from the front surface 42 toward the rear surface 44. A rear plate 48 is juxtaposed with the frame rear surface 44. The rear plate 48 includes a printed circuit 50 for connecting the electronic components together. A front plate 82, with a window 84, is juxtaposed with the frame front surface 42.

A graphic display plate 52 is disposed within the frame cavity 46. The graphic display plate 52 is made of a generally transparent material, typically acrylic. The graphic display plate 52 has graphic elements 66 displayed thereon. The graphic elements 66 are laser etched in reverse orientation through the rear surface 56 of the graphic display plate 66. The graphic elements 66 are viewed in proper orientation from the front 54. This process provides a three-dimensional image and leaves a smooth and unbroken front surface for an attractive display. The graphic elements 66 will be illuminated by LED (light-emitting diode) light entering the graphic display plate from two or more of the edges 58, 60, and ends 62, 64. The LED light is not visible as it passes edgewise through the acrylic plate, but becomes visible as it reflects from the 3-D graphic elements, and then passes through the graphic display plate front surface 54.

An illuminating means is provided by a plurality of illumination modules 68 arrayed at the bottom edge 36 and at the right 38 and left 40 ends of the frame 32. The frame 32 has LED cutouts 72 on either side of the frame cavity 46, and on the lower edge of the frame cavity 46. The LED cutouts 72 can each accommodate an illumination module 68. Each illumination module 68 contains a plurality of LEDs 70, and a digital logic circuit. The LEDs 70 face inward toward the graphic display plate 52. The digital logic circuit has electrical contacts facing rearward to contact the printed circuit 50. This provides illumination of the 3-D graphic elements 66 from opposite ends 62 and 64 of the graphic display plate 52.

Three button-type batteries 86 are held in three battery cutouts 88 on the lower edge of the frame cavity. The batteries 86 face rearward for contact with the printed circuit 50. A switch 74, with a push-button 80, is mounted in a switch cutout 76 on the lower edge of the frame cavity 46. The digital logic circuit selectively activates the LEDs 70 in a predetermined sequence, such as: flashing, strobe, sweep, fade, single color, multiple colors, random order, and sequential order. The digital logic circuit is not visible in the drawing, as it is inside the illumination module 68.

Attaching means is provided for attaching the name badge 30 to the clothing, such as a pin or a magnetic bar 90 and separate ferrous bar. Also shown is an easel arm 94 that pivots outward from the rear of the rear plate 48 to stand the name badge 30 on a table.

### BRIEF DESCRIPTION OF THE SEVERAL VIEWS OF THE DRAWING

A more complete understanding of the present invention may be obtained from consideration of the following description in conjunction with the drawing, in which:

FIG. 1 is an exploded, front perspective view of a name badge with an illuminated graphic display constructed in accordance with the invention, showing all parts exploded.

FIG. 2 is an exploded, front perspective view of the name badge with an illuminated graphic display of FIG. 1, showing two parts exploded.

FIG. 3 is an exploded, front perspective view of the name badge with an illuminated graphic display of FIG. 1, showing one part exploded.

FIG. 4 is a front perspective view of the name badge with an illuminated graphic display of FIG. 1, showing all parts assembled.

FIG. 5 is a rear perspective view of the name badge with an illuminated graphic display of FIG. 1, showing the easel arm deployed.

FIG. 6 is a rear perspective view of the name badge with an illuminated graphic display of FIG. 1, showing the magnetic bar clip deployed.

FIG. 7 is an exploded, rear perspective view of the name badge with an illuminated graphic display of FIG. 1

FIG. 8 is a front view of an insert of the name badge with an illuminated graphic display of FIG. 1, showing graphics and indicia.

FIG. 9 is a rear view of the insert of FIG. 8, showing the graphics and indicia laser etched in reverse.

FIG. 10 is a front view of another insert constructed in accordance with the invention, and showing another embodiment of graphics and indicia.

FIG. 11 is a rear view of the insert of FIG. 10, showing the graphics and indicia laser etched in reverse.

FIG. 12 is a front view of yet another insert constructed in accordance with the invention, and showing yet another embodiment of graphics and indicia.

FIG. 13 is a rear view of the insert of FIG. 12, showing the graphics and indicia laser etched in reverse.

FIG. 14 is an exploded, front perspective view of another embodiment of a name badge with an illuminated graphic display constructed in accordance with the invention, showing all parts exploded.

FIG. 15 is an exploded, front perspective view of the name badge with an illuminated graphic display of FIG. 14, showing one part exploded.

FIG. 16 is a front perspective view of the name badge with an illuminated graphic display of FIG. 14, showing all parts assembled, and an insert being installed.

FIG. 17 is a front perspective view of the name badge with an illuminated graphic display of FIG. 14, showing all parts assembled.

FIG. 18 is an exploded, front perspective view of still another embodiment of a name badge with an illuminated graphic display constructed in accordance with the invention, showing all parts exploded.

FIG. 19 is an exploded, front perspective view of the name badge with an illuminated graphic display of FIG. 18, showing two parts exploded.

FIG. 20 is an exploded, front perspective view of the name badge with an illuminated graphic display of FIG. 18, showing one part exploded.

FIG. 21 is a front perspective view of the name badge with an illuminated graphic display of FIG. 18, showing all parts assembled.

FIG. 22 is an exploded, front perspective view of a further embodiment of a name badge with an illuminated graphic display constructed in accordance with the invention, showing all parts exploded.

### DETAILED DESCRIPTION OF THE INVENTION

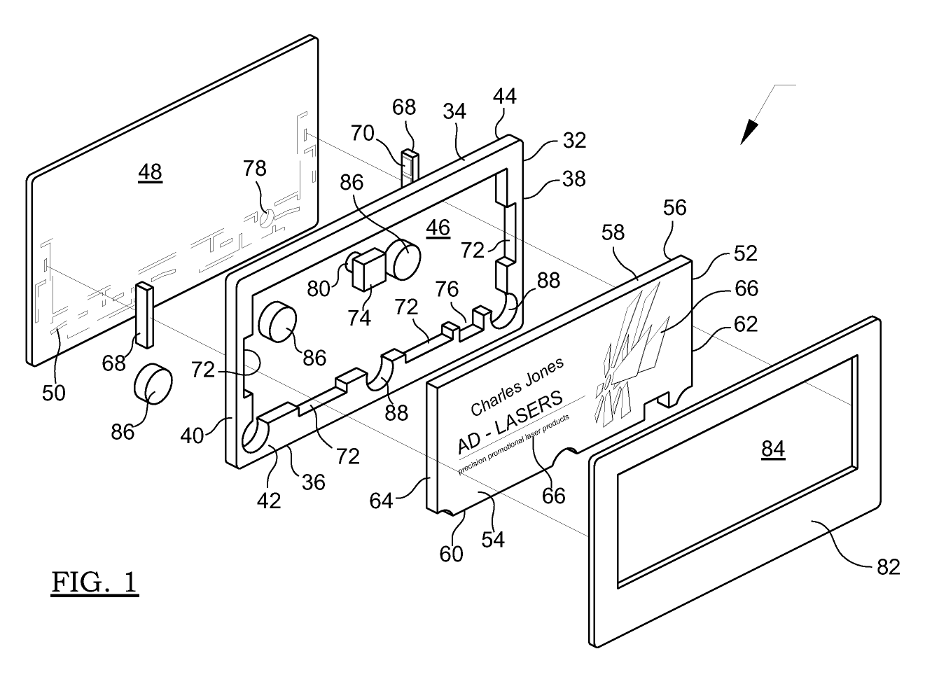

Referring now to the drawing, and especially to FIGS. 1-7 thereof, a name badge is shown at 30, and is to be worn on clothing. The name badge 30 comprises a frame 32 extending between opposite top 34 and bottom 36 edges, and between opposite right 38 and left 40 ends. The frame 32 extends between opposite front 42 and rear 44 surfaces. The frame 32 has a predetermined frame thickness between the front 42 and rear 44 surfaces. The frame 32 has a cavity 46 extending from the front surface 42 toward the rear surface 44.

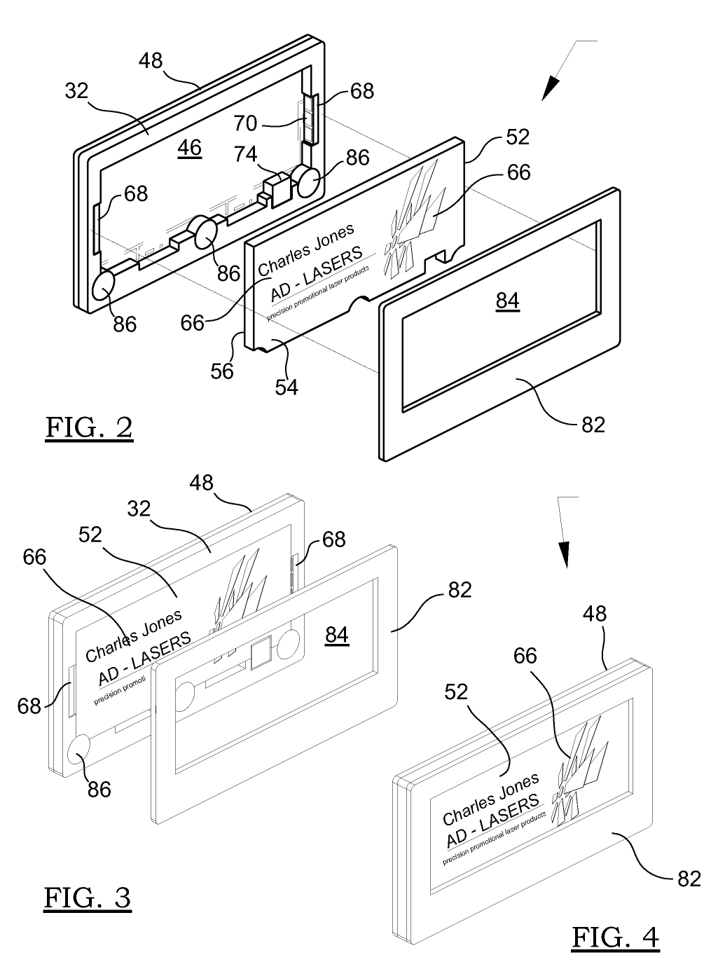

A rear plate 48 is juxtaposed with the frame rear surface 44. The rear plate 48 includes a printed circuit 50 for connecting the electronic components together. The printed circuit 50 shown in FIGS. 1 and 2 does not represent any specific wiring schematic, but is illustrative of where and how the circuit could be arranged on the rear plate 48. Details of how to connect the components are well known by those skilled in the electronic arts.

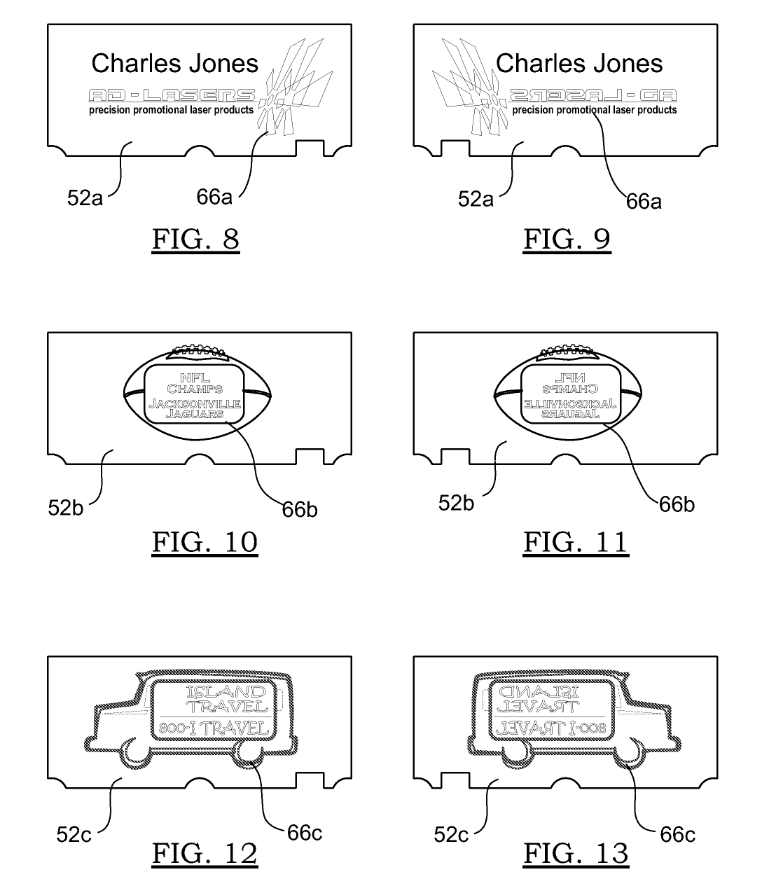

A graphic display plate 52 is disposed within the frame cavity 46. The graphic display plate 52 extends between opposite front 54 and rear 56 surfaces and between opposite top 58 and bottom 60 edges. The graphic display plate 52 extends between opposite right 62 and left 64 ends. The graphic display plate 52 is made of a generally transparent material, typically acrylic. However, any transparent, clear, translucent, or lightly tinted material will serve, such as polycarbonate, polyvinylchloride, glass, etc. The graphic display plate 52 has graphic elements 66 displayed thereon. The graphic elements 66 can be logos, designs, letters, numbers, or any artwork. The graphic elements 66 can be printed, molded, cast, engraved, or made by any process that will produce an image. In the preferred embodiment, the graphic elements 66 are laser etched in reverse orientation through the rear surface 56 of the graphic display plate 66. This is shown by examples 52a and 55a in FIGS. 9, 52b and 66b in FIGS. 11, and 52c and 66c in FIG. 13. The graphic elements 66 are viewed in proper orientation from the front 54, as shown in FIGS. 8, 10, and 12. These examples are only suggestive of the infinite variety of graphic elements 66 possible. The computer-controlled, laser etching process provides a three-dimensional image and leaves a smooth and unbroken front surface for an attractive display. The graphic elements 66 will be illuminated by LED (light-emitting diode) light entering the graphic display plate from at least one, and preferably two or more of the edges 58, 60, and ends 62, 64. The LED light is not visible as it passes edgewise through the acrylic plate. The LED light becomes visible as it reflects from the 3-D graphic elements, and then passes through the graphic display plate front surface 54.

An illuminating means is provided by a plurality of illumination modules 68 arrayed at the bottom edge 36 and at the right 38 and left 40 ends of the frame 32. The frame 32 has LED cutouts 72 on either side of the frame cavity 46 adjacent the frame ends 38 and 40, and on the lower edge of the frame cavity 46 adjacent the frame bottom edge 36. The LED cutouts 72 can each accommodate an illumination module 68. Each illumination module 68 contains an illumination source, typically a plurality of LEDs (light-emitting diodes) 70. Each illumination module 68 also contains a controlling means, specifically, a digital logic circuit. The LEDs 70 are arranged to face inward toward the graphic display plate 52. The digital logic circuit has electrical contacts (not shown) arranged to face rearward to contact the printed circuit 50. FIGS. 1 and 2 show the illumination modules 68 disposed at the frame ends 38 and 40. This provides illumination of the 3-D graphic elements 66 from opposite ends 62 and 64 of the graphic display plate 52, showing full brilliance and detail.

At least one battery 86 is provided. FIGS. 1-3 show three button-type batteries 86. The batteries 86 are held in three battery cutouts 88 on the lower edge of the frame cavity 46 adjacent the frame bottom edge 36. The batteries 86 face rearward for contact with the printed circuit 50.

A switch 74 is mounted in a switch cutout 76 on the lower edge of the frame cavity 46 adjacent the frame bottom edge 36. The switch 74 has a push-button 80 that passes through a switch hole 78 in the rear plate 48. The push-button 80 protrudes from the rear of the name badge 30 for easy activation.

The digital logic circuit is connected to the switch 74 and to the battery 86 through the printed circuit 50. The digital logic circuit selectively activates the LEDs 70 in a predetermined sequence. The predetermined sequence can consist of: flashing, strobe, sweep, fade, single color, multiple colors, random order, and sequential order. Many more sequences are possible, and fall within the scope of the claims. The digital logic circuit is not visible in the drawing, as it is inside the illumination module 68. Details of the digital logic circuit are well known to those skilled in the electronic arts.

A front plate 82 is juxtaposed with the frame front surface 42. The front plate 82 has a window 84 through which the graphic display plate 52 is visible.

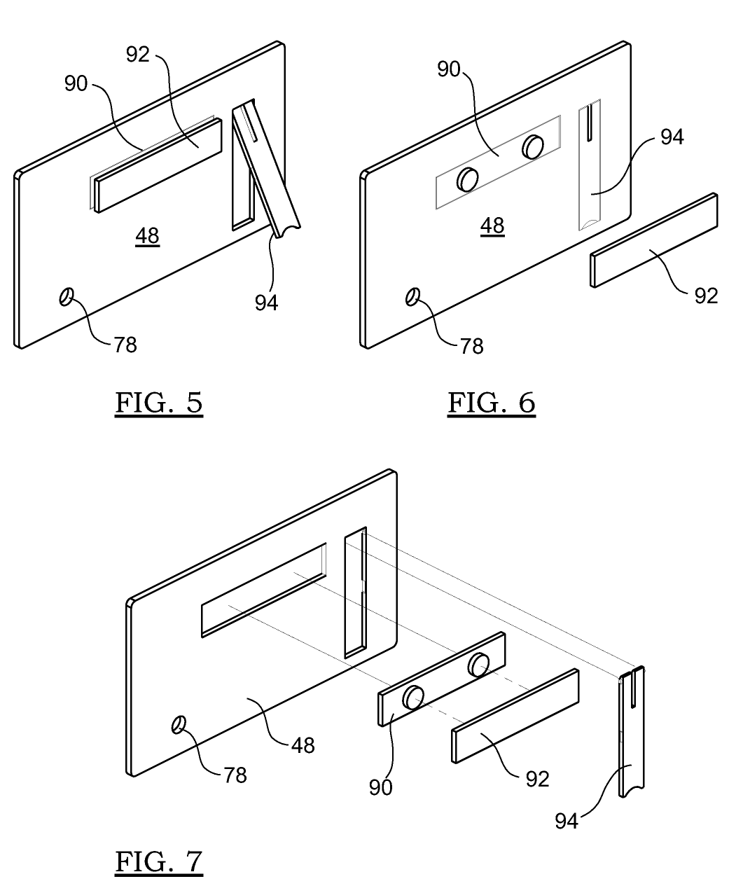

Attaching means is provided for attaching the name badge 30 to the clothing. This can be any number of common means, such as a pin. Shown in FIGS. 5-7 is a magnetic bar 90 attached to the rear of the name badge 30. A separate ferrous bar 92 is placed inside the clothing and juxtaposed with the magnetic bar 90 for holding the name badge 30 onto the clothing. Also shown is an easel arm 94 that pivots outward from the rear of the rear plate 48. The easel arm 94 allows the name badge 30 to stand alone on a table as a miniature sign.

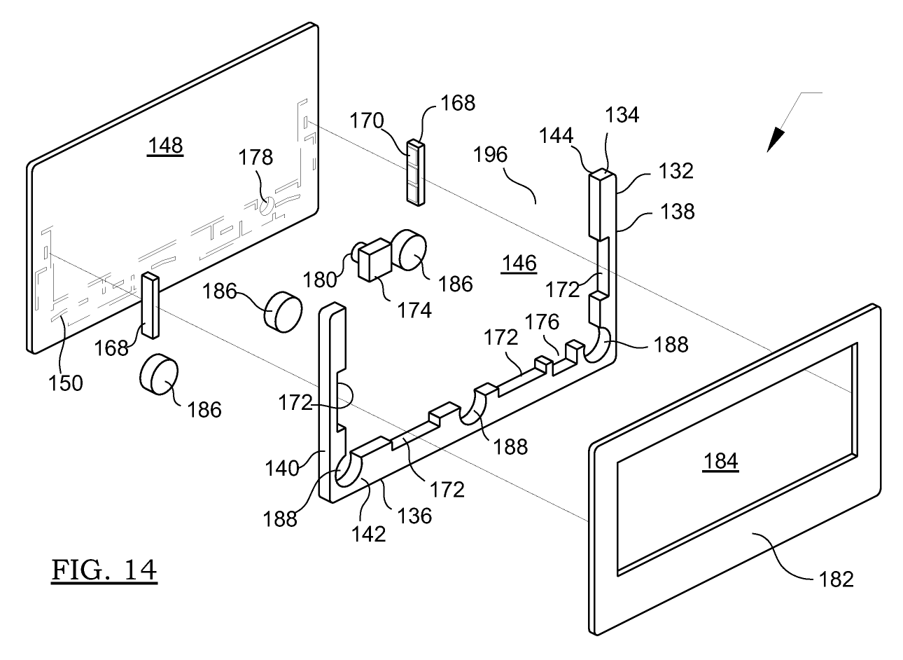

Turning now to the drawing FIGS. 14-17, as well as FIGS. 1-13 thereof, another name badge is shown at 130, and is similar to name badge 30 in that the name badge 130 comprises a frame 132 extending between opposite top 134 and bottom 136 edges, and between opposite right 138 and left 140 ends. The frame 132 extends between opposite front 142 and rear 144 surfaces. The frame 132 has a predetermined frame thickness between the front 142 and rear 144 surfaces. The frame 132 has a cavity 146 extending from the front surface 142 toward the rear surface 144.

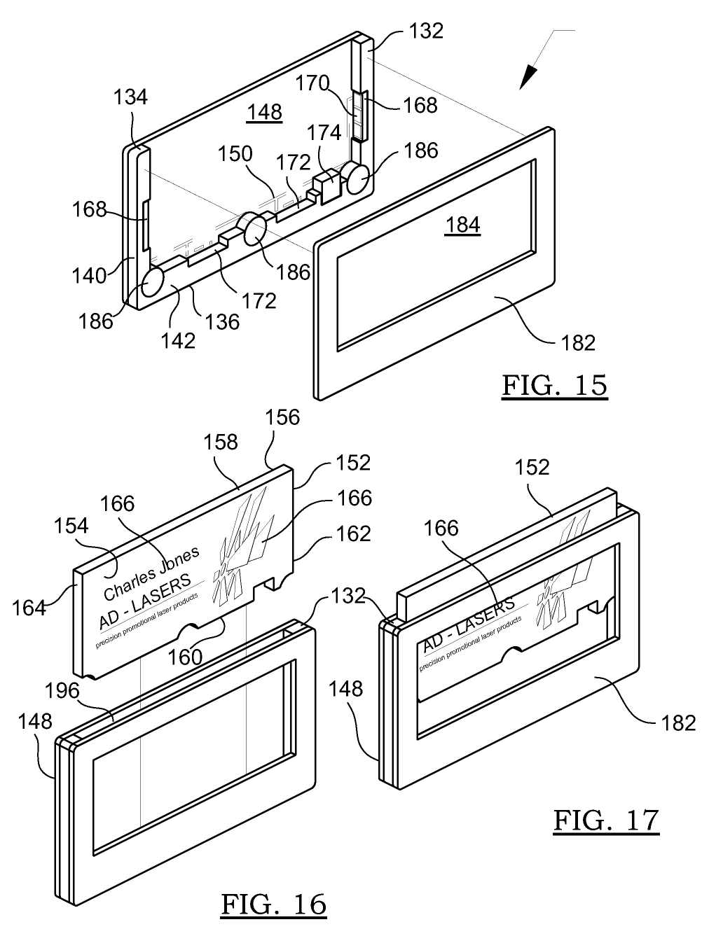

A rear plate 148 is juxtaposed with the frame rear surface 144. The rear plate 148 includes a printed circuit 150 for connecting the electronic components together. The printed circuit 150 shown in FIGS. 14 and 15 does not represent any specific wiring schematic, but is illustrative of where and how the circuit could be arranged on the rear plate 148. Details of how to connect the components are well known by those skilled in the electronic arts.

A graphic display plate 152 is disposed within the frame cavity 146. The graphic display plate 152 extends between opposite front 154 and rear 156 surfaces and between opposite top 158 and bottom 160 edges. The graphic display plate 152 extends between opposite right 162 and left 164 ends. The graphic display plate 152 is made of a generally transparent material, typically acrylic. The graphic display plate 152 has graphic elements 166 displayed thereon. The graphic elements 166 are laser etched in reverse orientation through the rear surface 156 of the graphic display plate 166. The graphic elements 166 are viewed in proper orientation from the front 154. The graphic elements 166 will be illuminated by LED (light-emitting diode) light entering the graphic display plate from two or more of the edges 158 and 60, and ends 162 and 164. The LED light is not visible as it passes edgewise through the acrylic plate. The LED light becomes visible as it reflects from the 3-D graphic elements, and then passes through the graphic display plate front surface 154.

An illuminating means is provided by a plurality of illumination modules 168 arrayed at the bottom edge 136 and at the right 138 and left 140 ends of the frame 132. The frame 132 has LED cutouts 172 on either side of the frame cavity 146 adjacent the frame ends 138 and 140, and on the lower edge of the frame cavity 146 adjacent the frame bottom edge 136. The LED cutouts 172 can each accommodate an illumination module 168. Each illumination module 168 contains an illumination source, typically a plurality of LEDs (light-emitting diodes) 170. Each illumination module 168 also contains a controlling means, specifically, a digital logic circuit. The LEDs 170 are arranged to face inward toward the graphic display plate 152. The digital logic circuit has electrical contacts (not shown) arranged to face rearward to contact the printed circuit 150. FIGS. 14 and 15 show the illumination modules 168 disposed at the frame ends 138 and 140. This provides illumination of the 3-D graphic elements 166 from opposite ends 162 and 164 of the graphic display plate 152, showing full brilliance and detail.

FIGS. 1-3 show three button-type batteries 186. The batteries 186 are held in three battery cutouts 188 on the lower edge of the frame cavity 146 adjacent the frame bottom edge 136. The batteries 186 face rearward for contact with the printed circuit 150.

A switch 174 is mounted in a switch cutout 176 on the lower edge of the frame cavity 146 adjacent the frame bottom edge 136. The switch 174 has a push-button 180 that passes through a switch hole 178 in the rear plate 148. The push-button 180 protrudes from the rear of the name badge 130 for easy activation.

The digital logic circuit is connected to the switch 174 and to the battery 186 through the printed circuit 150. The digital logic circuit selectively activates the LEDs 170 in a predetermined sequence. The digital logic circuit is not visible in the drawing, as it is inside the illumination module 168. Details of the digital logic circuit are well known to those skilled in the electronic arts.

A front plate 182 is juxtaposed with the frame front surface 142. The front plate 182 has a window 184 through which the graphic display plate 152 is visible.

Name badge 130 differs from name badge 30 in that the frame cavity 146 extends either upward or sideways, forming a slot 196. The graphic display plate 152 is adapted to be removably inserted through the slot 196 in either the frame top edge 134 or one of the frame ends 138 and 140. This allows another graphic display plate 152 to be selectively installed. The graphic display plate 152 has a thickness less than the predetermined frame thickness of the frame 132, so that the graphic display plate 152 will slide easily into and out of the slot 196.

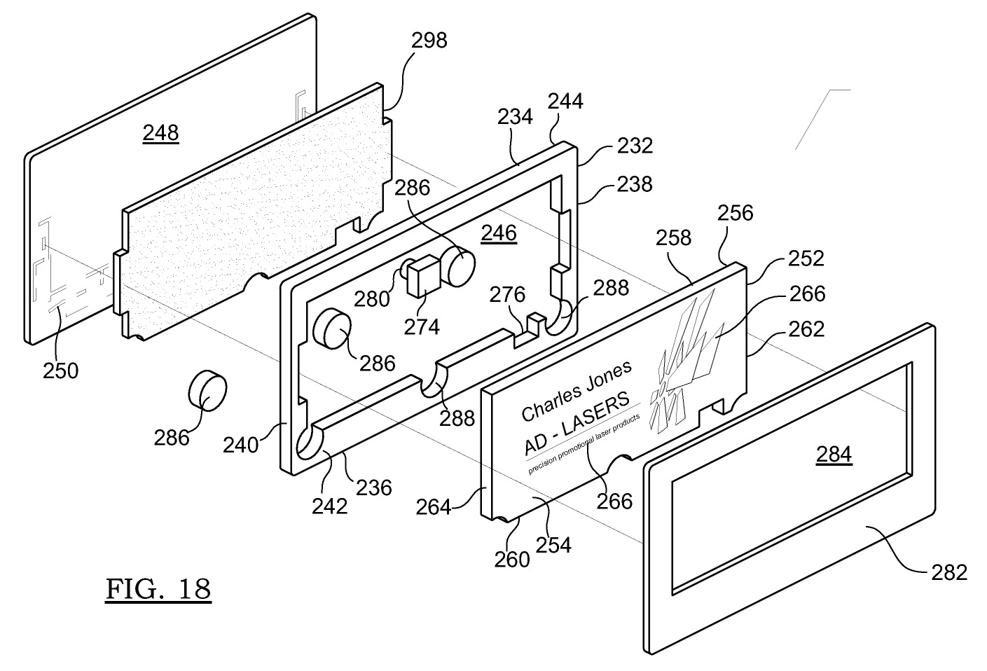

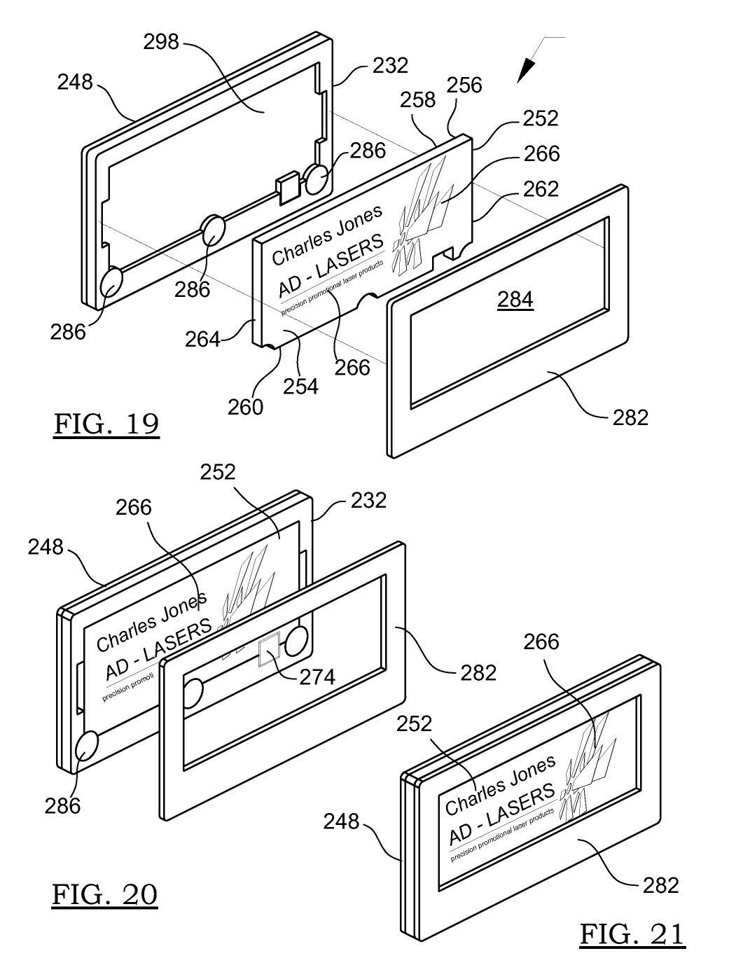

Referring now to the drawing FIGS. 18-21, as well as FIGS. 1-17 thereof, yet another embodiment of the name badge is shown at 230, and is similar to name badge 30 in that the name badge 230 comprises a frame 232 extending between opposite top 234 and bottom 236 edges, and between opposite right 238 and left 240 ends. The frame 232 extends between opposite front 242 and rear 244 surfaces. The frame 232 has a predetermined frame thickness between the front 242 and rear 244 surfaces. The frame 232 has a cavity 246 extending from the front surface 242 toward the rear surface 244.

A rear plate 248 is juxtaposed with the frame rear surface 244. The rear plate 248 includes a printed circuit 250 for connecting the electronic components together. The printed circuit 250 shown in FIG. 18 does not represent any specific wiring schematic, but is illustrative of where and how the circuit could be arranged on the rear plate 248. Details of how to connect the components are well known by those skilled in the electronic arts.

A graphic display plate 252 is disposed within the frame cavity 246. The graphic display plate 252 extends between opposite front 254 and rear 256 surfaces and between opposite top 258 and bottom 260 edges. The graphic display plate 252 extends between opposite right 262 and left 264 ends. The graphic display plate 252 is made of a generally transparent material, typically acrylic. The graphic display plate 252 has graphic elements 266 displayed thereon. The graphic elements 266 are laser etched in reverse orientation through the rear surface 256 of the graphic display plate 266. The graphic elements 266 are viewed in proper orientation from the front 254.

A front plate 282 is juxtaposed with the frame front surface 242. The front plate 282 has a window 284 through which the graphic display plate 252 is visible.

FIGS. 18-20 show three button-type batteries 286. The batteries 286 are held in three battery cutouts 288 on the lower edge of the frame cavity 246 adjacent the frame bottom edge 236. The batteries 286 face rearward for contact with the printed circuit 250.

A switch 274 is mounted in a switch cutout 276 on the lower edge of the frame cavity 246 adjacent the frame bottom edge 236. The switch 274 has a push-button 280 that passes through a switch hole (not shown) in the rear plate 248. The push-button 280 protrudes from the rear of the name badge 230 for easy activation.

Name badge 230 differs from name badge 30 in that an illumination source is provided by an electroluminescent panel 298 disposed adjacent the graphic display plate rear surface 256, and inside the frame cavity 246. The electroluminescent panel 298 provides illumination of the 3-D graphic elements 266 from behind the graphic display plate 252 by light passing through the graphic display plate 252 from the rear surface 256 to the front surface 254.

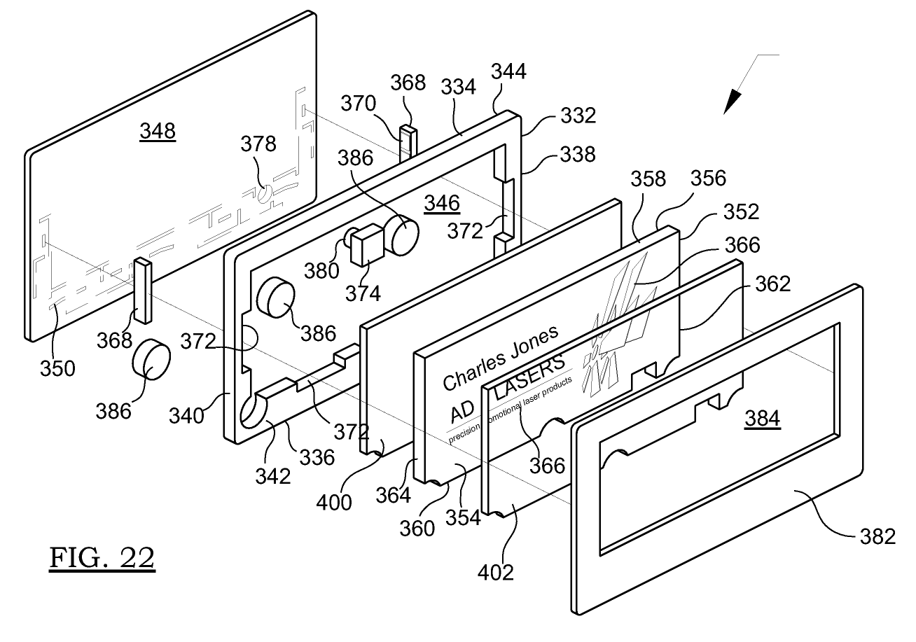

Turning now to the drawing FIG. 22, as well as FIGS. 1-17 thereof, another name badge is shown at 330, and is similar to name badge 30 in that the name badge 330 comprises a frame 332 extending between opposite top 334 and bottom 336 edges, and between opposite right 338 and left 340 ends. The frame 332 extends between opposite front 342 and rear 344 surfaces. The frame 332 has a predetermined frame thickness between the front 342 and rear 344 surfaces. The frame 332 has a cavity 346 extending from the front surface 342 toward the rear surface 344.

A rear plate 348 is juxtaposed with the frame rear surface 344. The rear plate 348 includes a printed circuit 350 for connecting the electronic components together. The printed circuit 350 shown in FIG. 22 does not represent any specific wiring schematic, but is illustrative of where and how the circuit could be arranged on the rear plate 348. Details of how to connect the components are well known by those skilled in the electronic arts.

A graphic display plate 352 is disposed within the frame cavity 346. The graphic display plate 352 extends between opposite front 354 and rear 356 surfaces and between opposite top 358 and bottom 360 edges. The graphic display plate 352 extends between opposite right 362 and left 364 ends. The graphic display plate 352 is made of a generally transparent material, typically acrylic. The graphic display plate 352 has graphic elements 366 displayed thereon. The graphic elements 366 are laser etched in reverse orientation through the rear surface 356 of the graphic display plate 366. The graphic elements 366 are viewed in proper orientation from the front 354. This process provides a three-dimensional image and leaves a smooth and unbroken front surface for an attractive display. The graphic elements 366 will be illuminated by LED (light-emitting diode) light entering the graphic display plate from at least one, and preferably two or more of the edges 358 and 360, and ends 362 and 364. The LED light is not visible as it passes edgewise through the acrylic plate. The LED light becomes visible as it reflects from the 3-D graphic elements, and then passes through the graphic display plate front surface 354.

An illuminating means is provided by a plurality of illumination modules 368 arrayed at the bottom edge 336 and at the right 338 and left 340 ends of the frame 332. The frame 332 has LED cutouts 372 on either side of the frame cavity 346 adjacent the frame ends 338 and 340, and on the lower edge of the frame cavity 346 adjacent the frame bottom edge 336. The LED cutouts 372 can each accommodate an illumination module 368. Each illumination module 368 contains an illumination source, typically a plurality of LEDs (light-emitting diodes) 370. Each illumination module 368 also contains a controlling means, specifically, a digital logic circuit. The LEDs 370 are arranged to face inward toward the graphic display plate 352. The digital logic circuit has electrical contacts (not shown) arranged to face rearward to contact the printed circuit 350. FIG. 22 shows the illumination modules 368 disposed at the frame ends 338 and 340. This provides illumination of the 3-D graphic elements 366 from opposite ends 362 and 364 of the graphic display plate 352, showing full brilliance and detail.

At least one battery 386 is provided. FIG. 22 shows three button-type batteries 386. The batteries 386 are held in three battery cutouts 388 on the lower edge of the frame cavity 346 adjacent the frame bottom edge 336. The batteries 386 face rearward for contact with the printed circuit 350.

A switch 374 is mounted in a switch cutout 376 on the lower edge of the frame cavity 346 adjacent the frame bottom edge 336. The switch 374 has a push-button 80 that passes through a switch hole 378 in the rear plate 348. The push-button 3380 protrudes from the rear of the name badge 330 for easy activation.

The digital logic circuit is connected to the switch 374 and to the battery 386 through the printed circuit 350. The digital logic circuit selectively activates the LEDs 370 in a predetermined sequence. The digital logic circuit is not visible in the drawing, as it is inside the illumination module 368. Details of the digital logic circuit are well known to those skilled in the electronic arts.

A front plate 382 is juxtaposed with the frame front surface 342. The front plate 382 has a window 384 through which the graphic display plate 352 is visible.

Name badge 330 differs from name badge 30 in that a reflective surface 400 is disposed adjacent the graphic display plate rear surface 356. The reflective surface 400 can be a coating on the graphic display plate rear surface 356. Alternatively, the reflective surface 400 can be a separate plate, as shown in FIG. 22. A semi-reflective surface 402 is disposed adjacent the graphic display plate front surface 354. The semi-reflective surface 402 is semi-transparent, so that it will both reflect some of the light, and transmit some of the light. The semi-reflective surface 402 can be a coating on the graphic display plate front surface 354. Alternatively, the semi-reflective surface 402 can be a separate plate, as shown in FIG. 22. The graphic elements 366 will be reflected between the reflective surface 400 and the semi-reflective surface 402 a multiplicity of times. The multiplicity of reflections will be visible through the semi-reflective surface 402.

An illuminating method is also disclosed for illuminating a name badge. The method comprises the steps of providing a frame, and extending the frame between opposite top and bottom edges and between opposite right and left ends and between opposite front and rear surfaces, then juxtaposing a rear plate with the frame rear surface. Next, extending a cavity from the frame front surface toward the frame rear surface, disposing a graphic display plate within the frame cavity, and extending the graphic display plate between opposite front and rear surfaces and between opposite top and bottom edges and between opposite right and left ends. Next, displaying graphic elements upon the graphic display plate, etching the graphic elements with a laser in reverse through the rear surface of the graphic display plate, providing a three-dimensional image and an unbroken front surface, and making the graphic display plate of a generally transparent material. Next, juxtaposing a front plate with the frame front surface, and providing a window in the front plate through which the graphic display plate is visible. Next, disposing at least one light-emitting diode adjacent one of the graphic display plate edges and ends, then disposing at least one battery within the frame, connecting the light-emitting diode to the battery, then controlling the light-emitting diode, and illuminating the graphic elements by passing light through the graphic display plate from at least one of the edges and ends, reflecting the light from the graphic elements, and passing the light through the graphic display plate front surface.

Further steps comprise disposing a plurality of light-emitting diodes adjacent one of the graphic display plate edges and ends, providing a switch, connecting a digital logic circuit to the switch and to the battery, and activating the light-emitting diodes selectively in a predetermined sequence with the digital logic circuit.

Yet further steps include extending the frame cavity through one of the frame edges and ends, and allowing the graphic display plate to be removably inserted through one of the frame edges and ends.

Still further steps include disposing a reflective surface adjacent the graphic display plate rear surface, disposing a semi-reflective surface adjacent the graphic display plate front surface, the semi-reflective surface being semi-transparent. Next, reflecting the graphic elements between the reflective surface and the semi-reflective surface a multiplicity of times, and allowing the graphic elements to be visible through the semi-reflective surface.

Numerous modifications and alternative embodiments of the invention will be apparent to those skilled in the art in view of the foregoing description. Accordingly, this description is to be construed as illustrative only and is for the purpose of teaching those skilled in the art the best mode of carrying out the invention. Details of the structure may be varied substantially without departing from the spirit of the invention and the exclusive use of all modifications that will come within the scope of the appended claims is reserved.

### PARTS LIST

### PART

### NO. DESCRIPTION

30 name badge
32 frame
34 frame top edge
36 frame bottom edge
38 frame right end
40 frame left end
42 frame front surface
44 frame rear surface
46 cavity
48 rear plate
50 printed circuit
52 graphic display plate
54 graphic display pl. front surface
56 graphic display pl. rear surface
58 graphic display pl. top edge
60 graphic display pl. bottom edge
62 graphic display pl. right end
64 graphic display pl. left end
66 graphic elements
68 illumination module
70 LED (light-emitting diode)
72 LED cutouts
74 switch
76 switch cutout
78 switch hole
80 push-button
82 front plate
84 front plate window
86 battery
88 battery cutout
90 magnetic bar
92 ferrous bar
94 easel arm
130 name badge
132 frame
134 frame top edge
136 frame bottom edge
138 frame right end
140 frame left end
142 frame front surface
144 frame rear surface
146 cavity
148 rear plate
150 printed circuit
152 graphic display plate
154 graphic display pl. front surface
156 graphic display pl. rear surface
158 graphic display pl. top edge
160 graphic display pl. bottom edge
162 graphic display pl. right end
164 graphic display pl. left end
166 graphic elements
168 illumination module
170 LED (light-emitting diode)
172 LED cutouts
174 switch
176 switch cutout
178 switch hole
180 push-button
182 front plate
184 front plate window
186 battery
188 battery cutout
196 slot
230 name badge
232 frame
234 frame top edge
236 frame bottom edge
238 frame right end
240 frame left end
242 frame front surface
244 frame rear surface
246 cavity
248 rear plate
250 printed circuit
252 graphic display plate
254 graphic display pl. front surface
256 graphic display pl. rear surface
258 graphic display pl. top edge
260 graphic display pl. bottom edge
262 graphic display pl. right end
264 graphic display pl. left end
266 graphic elements
274 switch
276 switch cutout
280 push-button
282 front plate
284 front plate window
286 battery
288 battery cutout
298 electroluminescent panel
330 name badge
332 frame
334 frame top edge
336 frame bottom edge
338 frame right edge
340 frame left edge
342 frame front surface
344 frame rear surface
346 cavity
348 rear plate
350 printed circuit
352 graphic display plate
354 graphic display pl. front surface
356 graphic display pl. rear surface
358 graphic display pl. top edge
360 graphic display pl. bottom edge
362 graphic display pl. right end
364 graphic display pl. left end
366 graphic elements
368 illumination module
370 LED (light-emitting diode)
372 LED cutouts
374 switch
376 switch cutout
378 switch hole
380 push-button
382 front plate
384 front plate window
386 battery
388 battery cutout
400 reflective surface
402 semi-reflective surface

The embodiments of the invention in which an exclusive property or privilege is claimed are defined as follows:

1. A name badge adapted to be worn on clothing, the name badge comprising:
a frame, the frame having front and rear surfaces, the frame having a cavity extending from the front surface toward the rear surface;
a graphic display plate adapted to be visibly disposed within the frame cavity, the graphic display plate having graphic elements displayed thereon;
a rear plate juxtaposed with the frame rear surface; and
illuminating means for illuminating the graphic display plate.

2. The name badge of claim 1, further comprising:
a front plate juxtaposed with the frame front surface, the front plate having a window through which the graphic display plate is visible; and
attaching means for attaching the name badge to the clothing.

3. The name badge of claim 1, further comprising:
the frame extending between opposite top and bottom edges and extending between opposite right and left ends;
the frame cavity extending through one of the frame edges and ends, so as to form a slot; and
the graphic display plate being adapted to be removably inserted through the slot on one of the edges and ends into the frame cavity, so as to allow another graphic display plate to be selectively installed.

4. The name badge of claim 1, wherein the illuminating means further comprises:
at least one illumination source disposed within the frame;
at least one battery disposed within the frame; and
controlling means connected between the illumination source and the battery for controlling the illumination source.

5. The name badge of claim 4, wherein:
the graphic display plate further comprises a generally transparent material extending between opposite front and rear surfaces; and
the illumination source further comprises an electroluminescent panel disposed adjacent the graphic display plate rear surface; so that
the graphic elements will be illuminated by light passing through the graphic display plate from the rear surface to the front surface.

6. The name badge of claim 4, wherein:
the graphic display plate further comprises transparent material extending between opposite front and rear surfaces and extending between opposite top and bottom edges and extending between opposite right and left ends; and
the illumination source further comprises at least one light-emitting diode disposed adjacent one of the graphic display plate edges and ends; so that
the graphic elements will be illuminated by light passing through the graphic display plate transversely from at least one of the edges and ends, reflecting from the graphic elements, and passing through the front surface.

7. The name badge of claim 6, further comprising the graphic elements being laser etched in reverse through the rear surface of the graphic display plate, so as to provide a three-dimensional image and an unbroken front surface.

8. The name badge of claim 6, wherein the illumination source further comprises a plurality of light-emitting diodes; and the controlling means further comprises:
a switch; and
a digital logic circuit connected to the switch and to the battery, the digital logic circuit being adapted to selectively activate the light-emitting diodes in a predetermined sequence.

9. The name badge of claim 8, wherein the predetermined sequence is selected from the group consisting of: flashing, strobe, sweep, fade, single color, multiple colors, random order, and sequential order.

10. The name badge of claim 1, further comprising:
the graphic display plate extending between opposite front and rear surfaces;
a reflective surface disposed adjacent the graphic display plate rear surface; and
a semi-reflective surface disposed adjacent the graphic display plate front surface, the semi-reflective surface being semi-transparent; so that
the graphic elements will be reflected between the reflective surface and the semi-reflective surface a multiplicity of times, and will be visible through the semi-reflective surface.

11. The name badge of claim 1, wherein the attaching means further comprises:
a magnet;
a ferrous bar, a one of the magnet and ferrous bar being attached to the name badge, and the other adapted to being disposed inside the clothing and adjacent the magnet; so that
the ferrous bar will be attracted to the magnet, so as to pinch the clothing between the ferrous bar and the magnet, thereby attaching the name badge to the clothing.

12. A name badge adapted to be worn on clothing, the name badge comprising:
a frame, the frame extending between opposite top and bottom edges and extending between opposite right and left ends and extending between opposite front and rear surfaces, the frame having a predetermined frame thickness between the front and rear surfaces, the frame having a cavity extending from the front surface toward the rear surface;
a rear plate juxtaposed with the frame rear surface;
a graphic display plate adapted to be visibly disposed within the frame cavity, the graphic display plate extending between opposite front and rear surfaces and extending between opposite top and bottom edges and extending between opposite right and left ends, the graphic display plate having graphic elements displayed thereon, the graphic elements being laser etched in reverse through the rear surface of the graphic display plate, so as to provide a three-dimensional image and an unbroken front surface, the graphic display plate being made of a generally transparent material;
a front plate juxtaposed with the frame front surface, the front plate having a window through which the graphic display plate is visible;
attaching means for attaching the name badge to the clothing;
at least one light-emitting diode disposed adjacent one of the graphic display plate edges and ends;
at least one battery disposed within the frame; and
controlling means connected between the light-emitting diode and the battery for controlling the light-emitting diode; so that
the graphic elements will be illuminated by light passing transversely through the graphic display plate from at least one of the edges and ends, reflecting from the graphic elements, and passing through the graphic display plate front surface.

13. The name badge of claim 12, wherein the light-emitting diode further comprises a plurality of light-emitting diodes; and the controlling means further comprises:
a switch; and
a digital logic circuit connected to the switch and to the battery, the digital logic circuit being adapted to selectively activate the light-emitting diodes in a predetermined sequence.

14. The name badge of claim 13, wherein the predetermined sequence is selected from the group consisting of: flashing, strobe, sweep, fade, single color, multiple colors, random order, and sequential order.

15. The name badge of claim 12, further comprising:
the frame cavity extending through one of the frame edges and ends, so as to form a slot; and
the graphic display plate being adapted to be removably inserted through the slot on one of the edges and ends into the frame cavity, so as to allow another graphic display plate to be selectively installed.

16. The name badge of claim 12, further comprising:
a reflective surface disposed adjacent the graphic display plate rear surface; and
a semi-reflective surface disposed adjacent the graphic display plate front surface, the semi-reflective surface being semi-transparent; so that
the graphic elements will be reflected between the reflective surface and the semi-reflective surface a multiplicity of times, and will be visible through the semi-reflective surface.

17. A method for illuminating a name badge, the name badge being adapted to be worn on clothing, the method comprising the steps of:
providing a frame, and extending the frame between opposite top and bottom edges and between opposite right and left ends and between opposite front and rear surfaces;
extending a cavity from the frame front surface toward the frame rear surface;
juxtaposing a rear plate with the frame rear surface;
disposing a graphic display plate within the frame cavity, and extending the graphic display plate between opposite front and rear surfaces and between opposite top and bottom edges and between opposite right and left ends;
displaying graphic elements upon the graphic display plate;
etching the graphic elements with a laser in reverse through the rear surface of the graphic display plate; thereby
providing a three-dimensional image and an unbroken front surface;
making the graphic display plate of a generally transparent material;
juxtaposing a front plate with the frame front surface;
providing a window in the front plate through which the graphic display plate is visible;
disposing at least one light-emitting diode adjacent one of the graphic display plate edges and ends;
disposing at least one battery within the frame;
connecting the light-emitting diode to the battery;
controlling the light-emitting diode; and
illuminating the graphic elements by passing light through the graphic display plate from at least one of the edges and ends, reflecting the light from the graphic elements, and passing the light through the graphic display plate front surface.

18. The method of claim 17, further comprising the steps of:
disposing a plurality of light-emitting diodes adjacent one of the graphic display plate edges and ends;
providing a switch;
connecting a digital logic circuit to the switch and to the battery; and
activating the light-emitting diodes selectively in a predetermined sequence with the digital logic circuit.

19. The method of claim 18, further comprising the steps of:
extending the frame cavity through one of the frame edges and ends, forming a slot; and
adapting the graphic display plate to be removably inserted through the slot in one of the frame edges and ends into the frame cavity; thereby
allowing another graphic display plate to be selectively installed.

20. The method of claim 18, further comprising the steps of:
disposing a reflective surface adjacent the graphic display plate rear surface;
disposing a semi-reflective surface adjacent the graphic display plate front surface, the semi-reflective surface being semi-transparent;
reflecting the graphic elements between the reflective surface and the semi-reflective surface a multiplicity of times; and
allowing the reflected graphic elements to be visible through the semi-reflective surface.
